(19) United States
(12) Patent Application Publication
(10) Pub. No.: US 2010/0001322 A1
(43) Pub. Date: Jan. 7, 2010

(54) SEMICONDUCTOR DEVICE

(75) Inventors: Wolfgang Euen, Boeblingen (DE); Holger Schligtenhorst, Stuttgart (DE); Rainer Bauer, Haiterbach (DE); Marc Van Geffen, Nufringen (DE); Karl-Heinz Kraft, Stuttgart (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/088,733

(22) PCT Filed: Oct. 5, 2006
(86) PCT No.: PCT/IB06/53642

§ 371 Date: May 13, 2009

(30) Foreign Application Priority Data
Oct. 6, 2005 (EP) 05109284.9

(51) Int. Cl. H01L 21/762; H01L 29/786; H01L 27/12

(52) U.S. Cl. 257/213; 438/458; 257/506; 257/E29.286; 257/E27.112; 257/E21.568

(57) ABSTRACT

The invention relates to a method of manufacturing a semiconductor device (10) with a substrate (11) and a semiconductor body (12) comprising silicon which is provided with at least one semiconductor element (T), wherein an epitaxial semiconductor layer (1) comprising silicon is grown on top of a first semiconductor substrate (14), wherein a splitting region (2) is formed in the epitaxial layer (1), wherein a second substrate (11) is attached by wafer bonding to the first substrate (12) at the side of the epitaxial layer (1) provided with the splitting region (2) while an electrically insulating region (3) is interposed between the epitaxial layer (1) and the second substrate (11), the structure thus formed is split at the location of the splitting region (2) as a result of which the second substrate (11) forms the substrate (11) with on top of the insulating region (3) a part (IA) of the epitaxial layer forming the semiconductor body (12) in which the semiconductor element (T) is formed. According to the invention for the thickness of the epitaxial layer (1) a thickness is chosen that is larger than about 3 μm. Preferably, the thickness is chosen between 5 and 15 μm. Best results are obtained with a thickness in the range of 7 to 13 μm. Devices 10, in particular high-voltage FETs, are obtained easily and with high yield and uniform properties like leakage current. The invention also comprises a method of manufacturing an SOI structure 12 and an SOI structure 12 thus obtained.

The invention relates to a method of manufacturing a semiconductor device with a substrate and a semiconductor body comprising silicon which is provided with at least one semiconductor element, wherein an epitaxial semiconductor layer comprising silicon is grown on top of a first semiconductor substrate, wherein a splitting region is formed in the epitaxial layer, wherein a second substrate is attached by wafer bonding to the first substrate at the side of the epitaxial layer provided with the splitting region while an electrically insulating region is interposed between the epitaxial layer and the second substrate, the structure thus formed is split at the location of the splitting region as a result of which the second substrate forms the substrate with on top of the insulating region a part of the epitaxial layer forming the semiconductor body in which the semiconductor element is formed.

The invention also relates to a semiconductor device obtained with such a method and to manufacturing method for a semiconductor body suitable for use in such a method and to a semiconductor body obtained with such a method.

Such a method is very suitable for making semiconductor devices like ICs (=Integrated Circuit). However, other devices such as discrete devices are obtainable as well by such a method.

A method as mentioned in the opening paragraph is known from JP-11-191617 that has been published on 13 Jul. 1999. In this document a method of manufacturing devices in a so-called SOI (=Semiconductor On Insulator) wafer structure is described. In a first embodiment a method is proposed in which an epitaxial layer of silicon with a thickness in the range of 0.5 to 2.5 μm is provided on a first silicon substrate. Subsequently an insulating region in the form of an oxide layer is formed on top of the epitaxial layer by thermal oxidation. Next a splitting region is formed in the epitaxial layer by implanting hydrogen ions through and below the oxide layer into the epitaxial layer. Next a second substrate of silicon is wafer bonded to the oxide layer on top of the epitaxial layer on the first substrate. After a splitting process in which the structure is ruptured at the splitting region the second substrate forms the substrate of the semiconductor device to be manufactured with on top of the insulating region a part of the epitaxial layer that forms a semiconductor body comprising silicon in which one or more semiconductor elements can be formed.

A drawback of such a method is that its yield of suitable semiconductor devices is rather low in case of semiconductor devices containing certain semiconductor elements, e.g. FETs and in particular high voltage FETs (=Field Effect Transistors).

It is therefore an object of the present invention to avoid the above drawbacks and to provide a method, which results in devices, in particular those that contain high voltage FETs with a high yield.

To achieve this, a method of the type described in the opening paragraph is characterized in that for the thickness of the epitaxial comprising a thickness is chosen that is larger than 3 micrometer. The invention is based on the surprising recognition that the yield of the manufacturing of in particular high voltage FETs is limited by the fact that the gate oxide of these FETs formed on top of the part of the epitaxial layer has a varying thickness in lateral directions which e.g. causes local differences in electric field and charge capacitance behavior for transistors. These differences result in e.g. differences in leakage current or breakdown characteristics through which the yield is reduced.

The invention further is based on the recognition that such a varying thickness of the gate oxide is caused by facets of certain pyramid shaped defects that cause a local different oxidation rate of the surface of the epitaxial layer. The thickness differences of the gate oxide, normally a thermal oxide, decrease or even vanish if the temperature at which the gate oxide is formed, is increased. However, such increased temperature intervenes with requirements of a low thermal budget in advanced processes. Finally, the invention is based on the recognition that such defects can be removed by increasing the thickness of the epitaxial layer to a value above 3 μm, preferably to a value in the range of 5 to 15μ.

Best results were obtained with a thickness value between 7 and 13 μm. Although higher thickness values are suitable as well, they increase the process time and are therefore to be avoided. This is quite surprisingly since the defects in question vary in size from 0.3 to 1.3 μm and one thus would expect that the influence of such defects would be vanished already at the usual thickness for the epitaxial layer.

With a method according to the invention semiconductor devices with high voltage, i.e. having operating voltages between 20 Volt and e.g. 150 Volt, FETs are obtainable with a high yield.

Preferably the splitting region is formed by a hydrogen implant at a distance from the surface of the epitaxial layer that lies between 0.05 and 2.0 micrometer. This implies that the semiconductor body comprising silicon has about the same thickness.

In an important embodiment of a method according to the invention, in which for the second substrate a semiconductor substrate is chosen and in which the electrically insulating region is formed by an electrically insulating layer, the electrically insulating layer is deposited or grown on the second substrate before the wafer bonding. It has been found that in this way the yield of the manufacturing process is further improved. This can be explained by the fact that position of the splitting region can be formed in a more homogeneous and accurate manner since the implantation is not done through the insulating region because in this preferred embodiment said region is present on the other (second) substrate.

The semiconductor element, in particular the high voltage FET is formed in the part of the epitaxial layer remaining on top of the insulating layer which in turn is on top of the second substrate, e.g. by forming a thermal oxide on top of the silicon and forming a gate region on top thereof while source and drain regions are formed in the surface of the semiconductor body by suitable ion implantations that border—viewed in projection—the gate region.

The invention further comprises a semiconductor device obtained with a method according to the invention.

Furthermore, a method of manufacturing a semiconductor body comprising silicon and a substrate wherein an epitaxial semiconductor layer comprising silicon is formed on top of a first semiconductor substrate, wherein a splitting region is formed in the epitaxial layer, wherein a second substrate is attached by wafer bonding to the first substrate at the side of the epitaxial layer provided with the splitting region while an electrically insulating region is interposed between the epitaxial layer and the second substrate, the structure thus formed is split at the location of the splitting region as a result of which the second substrate forms the substrate with on top of the insulating region a part of the epitaxial layer that forms the semiconductor body, is according to the invention, characterized in that for the thickness of the epitaxial layer a thickness is chosen that is larger than 3 micrometer. In this way a semiconductor body with a so-called SOI (=Semiconductor On Insulator) structure is obtained that can be used to form semiconductor devices like those that contain high-voltage FETs.

The semiconductor body obtained in this way forms in itself an attractive product since the device manufacture and the manufacture of the semiconductor body do not need to take place at one location or by one single manufacturer.

These and other aspects of the invention will be apparent from and elucidated with reference to the embodiments described hereinafter, to be read in conjunction with the drawing, in which

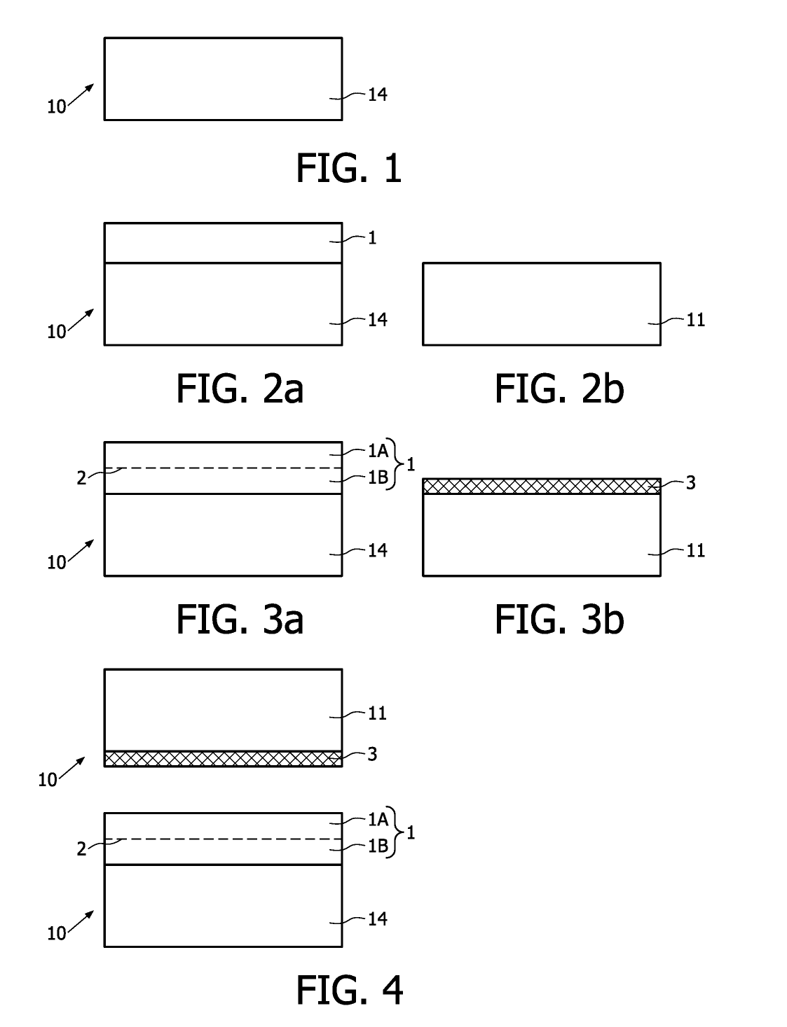

FIGS. 1 through 7 are sectional views of a semiconductor device at various stages in its manufacture by means of a method in accordance with the invention.

The Figures are diagrammatic and not drawn to scale, the dimensions in the thickness direction being particularly exaggerated for greater clarity. Corresponding parts are generally given the same reference numerals and the same hatching in the various Figures.

FIGS. 1 through 7 are sectional views of a semiconductor device at various stages in its manufacture by means of a method in accordance with the invention.

The semiconductor device manufactured in this example is a high voltage field effect transistor.

In a first step of the manufacture of device 10 (see FIG. 1) a first substrate 14, here of silicon, is provided with (see FIG. 2a) an epitaxial layer 1 comprising silicon, here of pure silicon, with a thickness of 12 μm. The deposition takes place at a pressure of 0.15 to 1 atm and a temperature of 1000 to 1200° C. The epi layer 1 is here p-type doped with a doping concentration of about 10¹⁵ at/cm³ (specific resistance of about 13 Ωcm).

Furthermore (see FIG. 2b) a second substrate 11 is prepared, here also of silicon and with a standard thickness. Both substrates 11,14 are here of the p-type conductivity and have a doping concentration ranging from that of intrinsic material to e.g. about 10¹⁵ at/cm³.

Next (see FIG. 3a) a splitting region 2 is formed in the silicon epitaxial layer 1 on the first substrate 14. This is done by performing an implantation of hydrogen in the epi layer 1. In this way said layer is “split” in two parts 1A,1B, the former having a thickness of 0.05 to 2.0 μm, in this example 1.5 μm, while the latter comprises about the remainder of the thickness of the epi layer 1. The implantation energy varies between 10 and 400 keV and is in this example 200 keV while the dose varies between 10¹⁶ and 10¹⁷ at/cm² and in this example is about 5×10¹⁶ at/cm².

Furthermore (see FIG. 3b) the second substrate 11 is provided with an electrically insulating layer 3, here in de form of a thermal silicon dioxide layer 3 which is provided by exposure to an oxygen containing ambient at a temperature of about 1050° C. The oxide layer 3 obtained has a thickness of 0.1 to 1 μm and is in this example 1 μm thick.

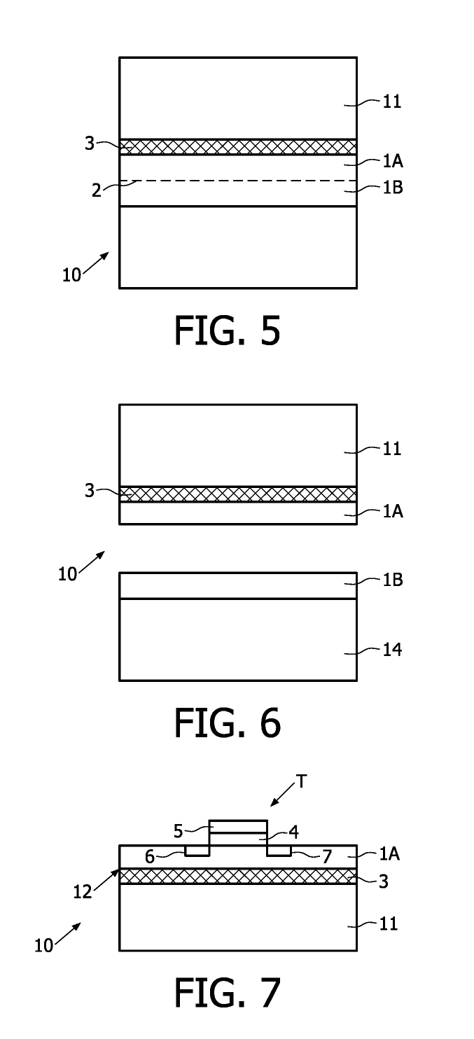

Subsequently (see FIG. 4), the second substrate 11 provided with the electrically insulating layer 3 is wafer bonded to the first substrate 14 at its side that is provided with the epitaxial layer 1 which in turn is already at this stage provided with the splitting region 2. The resulting structure is shown in FIG. 5.

Now (see FIG. 6) the structure of FIG. 5 is subjected to a splitting treatment, which comprises heating of the structure to a temperature in the range of 500 to 600° C., in this example at 500° C. in a furnace and under an atmosphere of N₂ at a pressure of 1 atm. By this treatment the structure of FIG. 5 is split into two parts on both sides of the splitting region 2, the upper part forming the device 10 to be manufactured at this stage and in the drawing shown upside down.

Next (see FIG. 7) the device 10 is shown upside up and with a transistor T being formed in the epitaxial layer 1A above the insulating layer 3. The transistor T has gate oxide 4, here a thermal oxide of 30 nm on top of which a gate region 5, e.g. of polycrystalline silicon is formed. Aligned with the gate region 5 n-type source and drain regions 6,7 are formed in the silicon of the epilayer part 1A. The MOS (=Metal Oxide Semiconductor) FET transistor T is designed and sized in this example in such a way that its operating voltage is in the range of 20 to 120 Volt. Both gate region 5 and source and drain regions 6,7 are provided with suitable connection regions that however are not shown in the drawing.

Individual devices 10 that are suitable for mounting are obtained after applying a separation technique like etching or sawing. Thanks to the method according to the invention the high-voltage MOSFET device 10 is obtained with a high yield and uniform properties.

It will be obvious that the invention is not limited to the examples described herein, and that within the scope of the invention many variations and modifications are possible to those skilled in the art.

For example it is to be noted although described for the manufacture of a discrete MOSFET device, the present invention is particularly suitable for the manufacture of (high-voltage) ICs like (C)MOS or BI(C)MOS ICs but also for bipolar ICs.

Furthermore it is noted that various modifications are possible with respect to individual steps. For example instead of a VPE (=Vapor Phase Epitaxy) other epitaxial growth techniques like MBE (=Molecular Beam Epitaxy) or ALE (Atomic Layer Epitaxy) can be used. For the insulating layer other deposition techniques may be used like CVD (=Chemical Vapor Deposition) and it may be made of other dielectric materials like silicon nitride. The epitaxial layer comprising silicon may comprise other materials like a mixed crystal of silicon and germanium.

The splitting region may also be formed in another way, like by implanting helium ions in stead of hydrogen ions into the epitaxial layer.

Finally it is to be noted that where in the example a step is mentioned to take place at the same time, this is not at all a necessary limitation but merely is an example.

1. Method of manufacturing a semiconductor device with a substrate and a semiconductor body comprising silicon which is provided with at least one semiconductor element, wherein an epitaxial semiconductor layer comprising silicon is grown on top of a first semiconductor substrate, wherein a splitting region is formed in the epitaxial layer, wherein a second substrate is attached by wafer bonding to the first substrate at the side of the epitaxial layer provided with the splitting region while an electrically insulating region is interposed between the epitaxial layer and the second substrate, the structure thus formed is split at the location of the splitting region as a result of which the second substrate forms the substrate with on top of the insulating region a part of the epitaxial layer forming the semiconductor body in which the semiconductor element is formed, characterized in that for the thickness of the epitaxial layer a thickness is chosen that is larger than about 3 micrometer.

2. Method according to claim 1, characterized in that for the thickness of the epitaxial layer a thickness is chosen between about 5 and about 15 micrometers.

3. Method according to claim 1, characterized in that for the thickness of the epitaxial layer a thickness is chosen between about 7 and about 13 micrometers.

4. Method according to claim 1, characterized in that the splitting region is formed by a hydrogen implant at a distance below the surface of the epitaxial layer that lies between about 0 and about 2 micrometers.

5. Method according to claim 1, wherein for the second substrate a semiconductor substrate is chosen and the electrically insulating region is formed by an electrically insulating layer, characterized in that the electrically insulating layer is deposited or grown on the second substrate before the wafer bonding.

6. Method according to claim 1, characterized in that for the semiconductor element a field effect transistor is chosen.

7. Method according to claim 6, characterized in that for the field effect transistor a high voltage field effect transistor is chosen.

8. Semiconductor device obtained by a method according to claim 1.

9. Method of manufacturing a semiconductor body comprising silicon and a substrate wherein an epitaxial semiconductor layer comprising silicon is formed on top of a first semiconductor substrate, wherein a splitting region is formed in the epitaxial layer, wherein a second substrate is attached by wafer bonding to the first substrate at the side of the epitaxial layer provided with the splitting region while an electrically insulating region is interposed between the epitaxial layer and the second substrate, the structure thus formed is split at the location of the splitting region as a result of which the second substrate forms the substrate with on top of the insulating region a part of the epitaxial layer that forms the semiconductor body, characterized in that for the thickness of the epitaxial layer a thickness is chosen that is larger than about 3 micrometers.

10. Semiconductor body obtained by a method according to claim 9.
